(19) United States
(12) Patent Application Publication
(10) Pub. No.: US 2026/0059661 A1
(43) Pub. Date: Feb. 26, 2026

(54) ELECTRONIC PACKAGE AND CARRIER STRUCTURE THEREOF

(71) Applicant: SILICONWARE PRECISION INDUSTRIES CO., LTD., Taichung City (TW)

(72) Inventors: Wen-Chen HSIEH, Taichung City (TW); Chia-Wen TSAO, Taichung City (TW); Yi-Lin TSAI, Taichung City (TW); Jia-Ci LIN, Taichung City (TW); Hsiu-Fang CHIEN, Taichung City (TW)

(73) Assignee: SILICONWARE PRECISION INDUSTRIES CO., LTD., Taichung City (TW)

(21) Appl. No.: 18/903,469

(22) Filed: Oct. 1, 2024

(30) Foreign Application Priority Data
Aug. 20, 2024 (TW) 113131311

(51) Int. Cl. H05K 1/11

(52) U.S. Cl. CPC H05K 1/111; H05K 2201/09036

(57) ABSTRACT

An electronic package and a carrier structure thereof are provided, in which a filler is formed between a pair of corresponding bonding pads to support an electronic element. The filler includes a first section and a second section. The first section is connected to the bonding pads, the second section intersects with the first section, and the second section is spaced apart from the bonding pads at a distance to avoid electrical bridging problems when the electronic element is electrically connected to the bonding pads via solder material.

### BACKGROUND

### 1. Technical Field

The present disclosure relates to a semiconductor packaging structure, and more particularly, to an electronic package and a carrier structure thereof.

### 2. Description of Related Art

With the advancement of integrated circuit manufacturing technology, the design and manufacture of electronic packages continue to develop toward miniaturization, and since they have large-scale, high-integration electronic circuits, therefore the functions of application products are relatively more complete.

Under this circumstance, electronic packages that are traditionally assembled on circuit boards using through hole technology (THT) cannot be further reduced in dimension, thereby they occupy a large amount of space on the circuit board, and through hole technology requires to drill holes on the circuit board according to each pin position of each electronic package, therefore pins of this type of electronic package will actually occupy the space on the opposite sides of the circuit board, and the solder joints at the connection between the electronic package and the circuit board are also larger. Therefore, the current assembly procedure of electronic devices has largely adopted surface-mount technology (SMT) to assemble electronic packages on circuit boards.

For electronic packages using SMT, since each electrode terminal (or pin) is soldered to the same surface of a circuit board, there is no need to drill holes on the circuit board. In other words, using SMT will allow different electronic packages to be assembled on opposite sides of the circuit board at the same time, thereby greatly improving the space utilization of the circuit board. In addition, due to the small volume of electronic packages adopting SMT, compared with traditional THT electronic packages, the number of electronic packages using SMT can be placed on the circuit board in a denser manner, so that the requirements of lightness, thinness, shortness, smallness, multi-function, high-speed and high-frequency of the electronic device can be met, such that the SMT assembly method has become the mainstream assembly method.

FIG. 1A and FIG. 1B are schematic cross-sectional and partial top views showing a conventional electronic package 1 assembled using SMT. In the electronic package 1, a substrate body 10 which surface is covered with a solder mask layer 13 is provided, and the substrate body 10 has a plurality of bonding pads 100 exposed from openings 130 of the solder mask layer 13, and then solder paste 12 is formed on the bonding pads 100 exposed from the solder mask layer 13 by using screen printing technology. Then, electrode terminals 110 of a passive element 11 are bonded to the solder paste 12 and the solder paste 12 is reflowed, so the electrode terminals 110 of the passive element 11 are electrically connected to the bonding pads 100 of the substrate body 10. Afterwards, an adhesive material 14 is filled into the space below the passive element 11 to fix the passive element 11 on the substrate body 10.

However, in the conventional electronic package 1, due to the limitation imposed by the passive element 11, it is difficult for the glue injection machine to fill the lower space of the passive element 11 with the adhesive material 14 during glue injection process, so voids P are prone to be formed, or the solder paste 12 may overflow due to the inability to fill the lower space, resulting in solder bridging problems. Even if the adhesive material 14 fills the lower space of the passive element 11, the solder paste 12 will still overflow along the contact edges of the adhesive material 14 and the passive element 11, resulting in solder bridging.

Therefore, how to overcome the aforementioned problems of the prior art has become an urgent issue to be solved.

### SUMMARY

In view of the aforementioned shortcomings of the prior art, the present disclosure provides a carrier structure, which comprises: a substrate body having a plurality of bonding pads; and an insulating protective layer formed on the substrate body and having a plurality of openings correspondingly exposing the plurality of bonding pads and a slot communicating the plurality of openings, wherein the slot comprises a first slot connecting two adjacent ones of the plurality of openings and a second slot intersecting with the first slot, and the second slot is spaced apart from the bonding pads by a distance.

The present disclosure further provides an electronic package, which comprises: a carrier structure comprising a substrate body and an insulating protective layer formed on the substrate body, wherein the substrate body has a plurality of bonding pads, the insulating protective layer is formed with a plurality of openings for correspondingly exposing the plurality of bonding pads and a slot communicating the plurality of openings, wherein the slot comprises a first slot connecting two adjacent ones of the plurality of openings and a second slot intersecting with the first slot, and the second slot is spaced apart from the bonding pads by a distance; a filler formed in the slot and comprising a first section corresponding to the first slot and a second section corresponding to the second slot, wherein the second section and the bonding pads are spaced by a distance therebetween; and an electronic element disposed on the filler and electrically connected to two adjacent ones of the bonding pads via a solder material.

In the aforementioned electronic package and carrier structure, the slot is in a cross shape and comprises the first slot and the second slot intersecting with the first slot.

In the aforementioned electronic package and carrier structure, the slot is in a serially-connected convex shape and comprises two of the first slots and the second slot intersecting with the two of the first slots.

In the aforementioned electronic package and carrier structure, a portion of the insulating protective layer is disposed between the second slot and the bonding pads.

In the aforementioned electronic package and carrier structure, the plurality of bonding pads are arranged in pairs in a row, and the slots located between the pairs of the bonding pads are also connected to each other in a row.

In the aforementioned electronic package and carrier structure, the bonding pads are in a convex shape, and outer convex portions of a pair of the bonding pads are opposite to each other.

In the aforementioned electronic package and carrier structure, the filler is in contact with and bonded to the electronic element and the substrate body.

In the aforementioned electronic package and carrier structure, the electronic element is disposed on the first slot and two adjacent ones of the openings communicated by the first slot.

In the aforementioned electronic package and carrier structure, the filler is in a cross shape or in a serially-connected convex shape.

In the aforementioned electronic package and carrier structure, the first section of the filler corresponds to the first slot and a portion of the opening.

In the aforementioned electronic package and carrier structure, a portion of the insulating protective layer remains between a bottom of the filler and the bonding pads.

In the aforementioned electronic package and carrier structure, the plurality of bonding pads are arranged in pairs in a row, and the fillers located between the pairs of the bonding pads are also connected to each other in a row.

As can be seen from the above, in the electronic package and carrier structure thereof of the present disclosure, a filler is formed between a pair of corresponding bonding pads to support the electronic element, the filler includes a first section connecting the bonding pads and a second section intersecting with the first section at the same time, and the second section is spaced apart from the bonding pads by a distance, thereby preventing the solder material from bridging at edges of the electronic element or the filler and from causing problems such as abnormalities or poor appearance when the electronic element is electrically connected to the bonding pads via the solder material.

### BRIEF DESCRIPTION OF THE DRAWINGS

FIG. 1A is a schematic cross-sectional view showing a conventional electronic package.

FIG. 1B is a schematic partial top planar view of FIG. 1A.

FIG. 2A is a schematic cross-sectional view showing an electronic package and a carrier structure of the present disclosure.

FIG. 2B is a schematic partial top planar view of FIG. 2A.

FIG. 3 is a schematic partial top planar view of a second embodiment of an electronic package of the present disclosure.

FIG. 4 is a schematic partial top planar view of a third embodiment of an electronic package of the present disclosure.

FIG. 5 is a schematic partial top planar view of a fourth embodiment of an electronic package of the present disclosure.

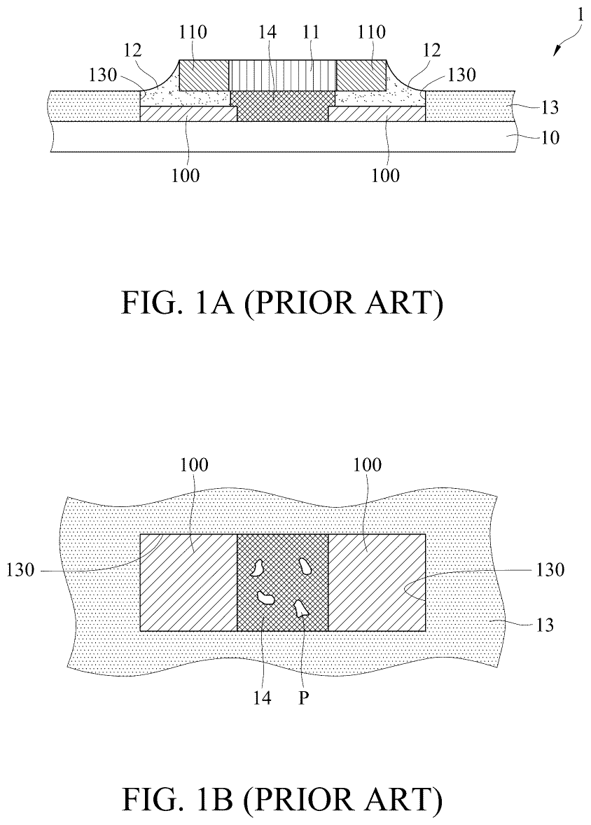

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

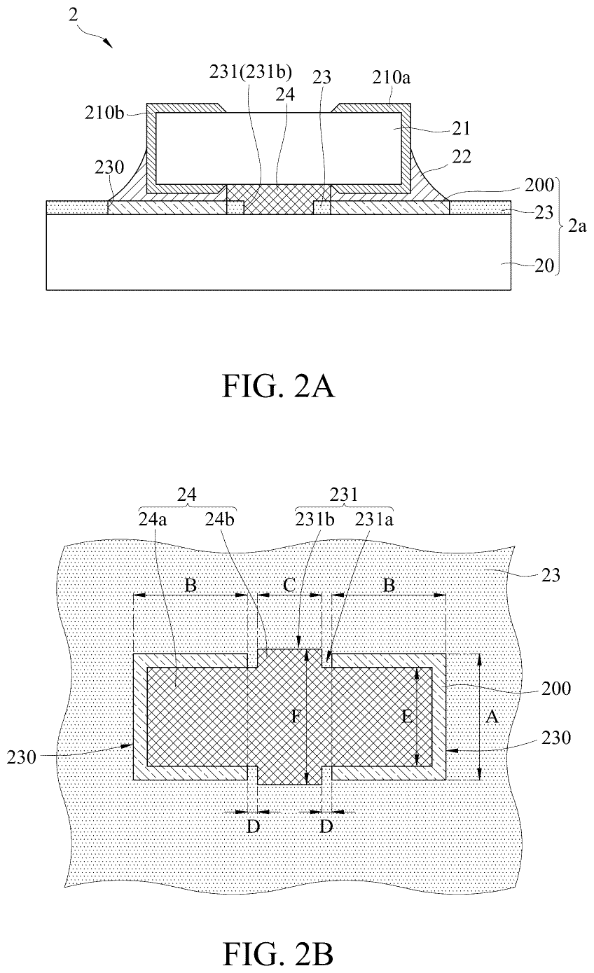

FIG. 2A and FIG. 2B are schematic cross-sectional and partial top views showing an electronic package 2 and a carrier structure 2a of the present disclosure. As shown in the drawings, the electronic package 2 includes the carrier structure 2a, an electronic element 21 disposed on the carrier structure 2a, and a filler 24 formed between the electronic element 21 and the carrier structure 2a.

The carrier structure 2a includes a substrate body 20. The substrate body 20 is, for example, a packaging substrate with a core layer and a substrate body, a packaging substrate with a substrate body in a coreless form, a through-silicon interposer (TSI) with through-silicon vias (TSVs), or other boards. The substrate body 20 includes at least an insulating layer and at least a circuit layer bonded to the insulating layer, such as at least a fan-out redistribution layer (RDL), and the outermost circuit layer has a plurality of bonding pads 200.

In one embodiment, the carrier structure 2a also includes an insulating protective layer 23 (made of such as green paint, ink, or other solder-resist materials) formed on the substrate body 20, and the insulating protective layer 23 has a plurality of openings 230 and a slot 231 communicating two of the openings 230, thereby each of the bonding pads 200 is correspondingly exposed from each of the openings 230, wherein the two communicating openings 230 and the slot 231 are served as an opening area.

Moreover, the slot 231 is approximately in a cross shape and has a first slot 231a (for example, in a transverse direction) and a second slot 231b (for example, in a longitudinal direction) that are perpendicular to each other, wherein the transverse first slot 231a communicates the two openings 230 so that the electronic element 21 is disposed on the two openings 230 and the first slot 231a, the longitudinal second slot 231b intersects the first slot 231a to form a junction area, and the longitudinal second slot 231b and the opening 230 (the bonding pad 200) are spaced apart by a dimension D and do not contact each other (for example, as shown in FIG. 2A, a portion of the insulating protective layer 23 is still between the slot 231 [the second slot 231b] and the bonding pad 200).

In one embodiment, the bonding pad 200 exposed from the opening 230 is rectangular and has the adjacent two lengths of dimensions A and B, the adjacent two lengths of the second slot 231b (corresponding to and parallel to the length dimensions A and B of the bonding pad 200) are dimensions F and C, and the adjacent two lengths of the first slot 231a (corresponding to and parallel to the length dimensions A and B of the bonding pad 200) are dimensions E and C+2D. The dimension B is about 0.73 times of the dimension A, the dimension C is about 0.4 times of the dimension A, the dimension D is about 0.08-0.17 times of the dimension A, the dimension E can be designed according to requirement but smaller than the dimension A, and the dimension F can be designed according to requirement but larger than the dimension E.

The filler 24 is formed on the slot 231 and a portion of the opening 230 to contact and bond to the substrate body 20 and a portion of the bonding pad 200, thereby a portion of the bonding pad 200 is exposed from the filler 24. In other words, the shape of the filler 24 is similar to the shape of the opening area, and the dimension of the filler 24 is slightly smaller than the dimension of the opening area, so as to expose a portion of the bonding pad 200 to allow the electronic element 21 to be electrically connected to the bonding pad 200.

In one embodiment, the top view shape of the filler 24 is similar to the shape of the opening area (the cross shape as shown in FIG. 2B), so the filler 24 has a first section 24a (for example, in a transverse direction) corresponding to the first slot 231a and a portion of the opening 230, and the filler 24 has a second section 24b (for example, in a longitudinal direction) corresponding to the second slot 231b, wherein the second section 24b of the filler 24 and the bonding pad 200 still keep a distance of dimension D therebetween, so the filler 24 has a T-shaped longitudinal cross section, and a portion of the insulating protective layer 23 remains between the bottom of the filler 24 and the bonding pad 200.

In addition, the filler 24 is made of an insulating material such as polyimide (PI), dry film, prepreg (PP), bismaleimide triazine (BT), or molding colloid or molding compound such as epoxy, but not limited to the above.

The electronic element 21 is disposed on the filler 24, so that the filler 24 is in contact with and bonded to the electronic element 21 and the substrate body 20. The electronic element 21 has a first electrode terminal 210a and a second electrode terminal 210b, and the first electrode terminal 210a and the second electrode terminal 210b are respectively bonded to the corresponding bonding pads 200. In one embodiment, the electronic element 21 is a passive element such as a resistor, a capacitor, or an inductor.

Furthermore, the first electrode terminal 210a and the second electrode terminal 210b are respectively bonded to the corresponding bonding pads 200 via solder material 22. Therefore, during assembly, after the solder material 22 is reflowed, the electronic element 21 can be electrically connected to the bonding pads 200 via the first electrode terminal 210a and the second electrode terminal 210b thereof.

Through the aforementioned design regarding that the longitudinal second slot 231b of the slot 231 and the opening 230 (the bonding pad 200) are spaced apart by a dimension D and do not contact each other (i.e., a portion of the insulating protective layer 23 is still between the second slot 231b and the bonding pad 200), so when the first electrode terminal 210a and the second electrode terminal 210b of the electronic element 21 are respectively bonded to the corresponding bonding pads 200 via the solder material 22, the solder material 22 can be prevented from bridging at edges of the electronic element 21 or the filler 24 and from causing problems such as abnormalities or poor appearance.

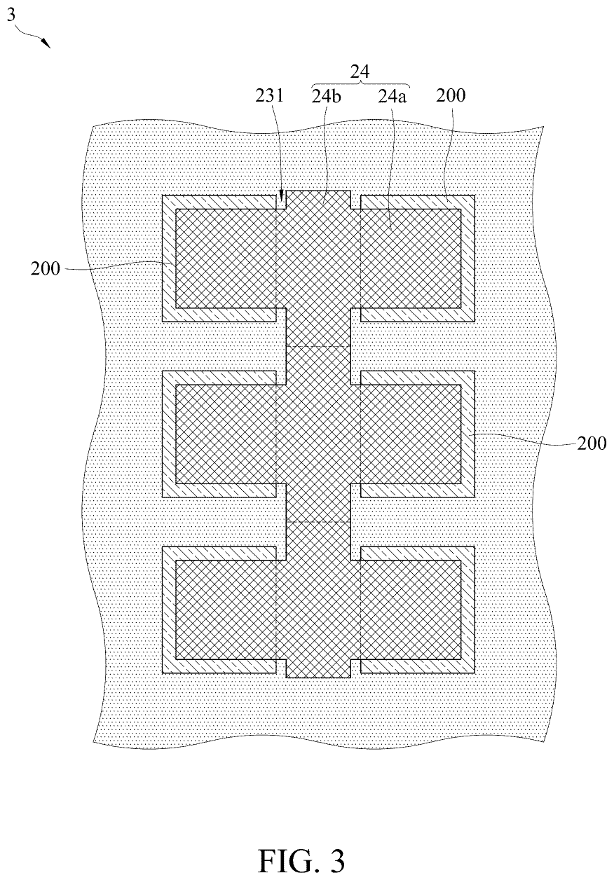

Please refer to FIG. 3, which is a schematic partial top planar view of a second embodiment of an electronic package 3 of the present disclosure. The embodiment is roughly the same as the previous embodiment, the main difference is that a plurality of bonding pads 200 (roughly rectangular) are formed on the carrier structure, and the plurality of bonding pads 200 are arranged in pairs in a row, the fillers 24 (or the slots 231) located between the pairs of bonding pads 200 at the same time are also connected to each other in a row.

Each filler 24 (roughly in a cross shape and has the first section 24a and the second section 24b intersecting with the first section 24a) located between two bonding pads 200 is connected to the second section 24b of the adjacent filler 24 via the second section 24b thereof, wherein the second section 24b and the bonding pad 200 keep a distance therebetween.

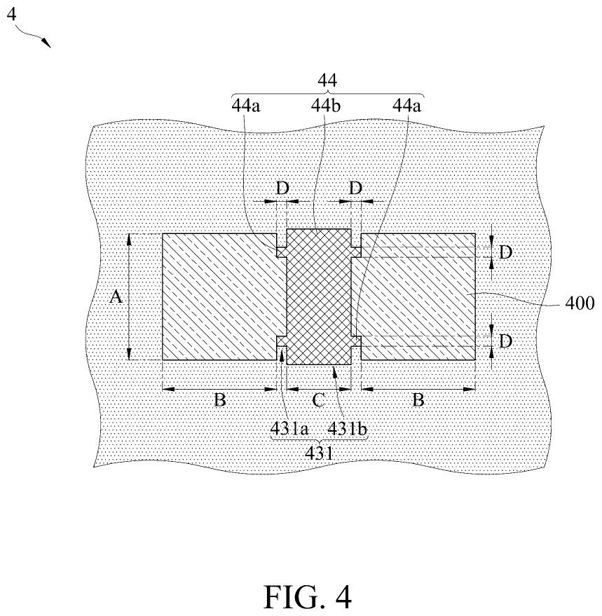

Please refer to FIG. 4, which is a schematic partial top planar view of a third embodiment of an electronic package 4 of the present disclosure. The embodiment is roughly the same as the previous embodiment, the main difference is that the bonding pad 400 exposed from the insulating protective layer on the carrier structure is roughly in a convex shape (e.g., in a shape of “T” or in a shape of Chinese character “ [symbol] ”), and the outer convex portions of the pair of the bonding pads 400 are opposite to each other.

Another slot 431 formed between pair of the bonding pads 400 is roughly in a serially-connected convex shape (e.g., in a shape of Chinese character “ [symbol] ”) and has two first slots 431a and one second slot 431b intersecting with the two first slots 431a. The filler 44 may correspond to the shape of the slot 431, that is, the filler 44 has two first sections 44a connecting to the pair of the bonding pads 400, and the filler 44 has a second section 44b intersecting with the two first sections 44a, wherein the second section 44b and the bonding pad 400 keep a distance of dimension D therebetween.

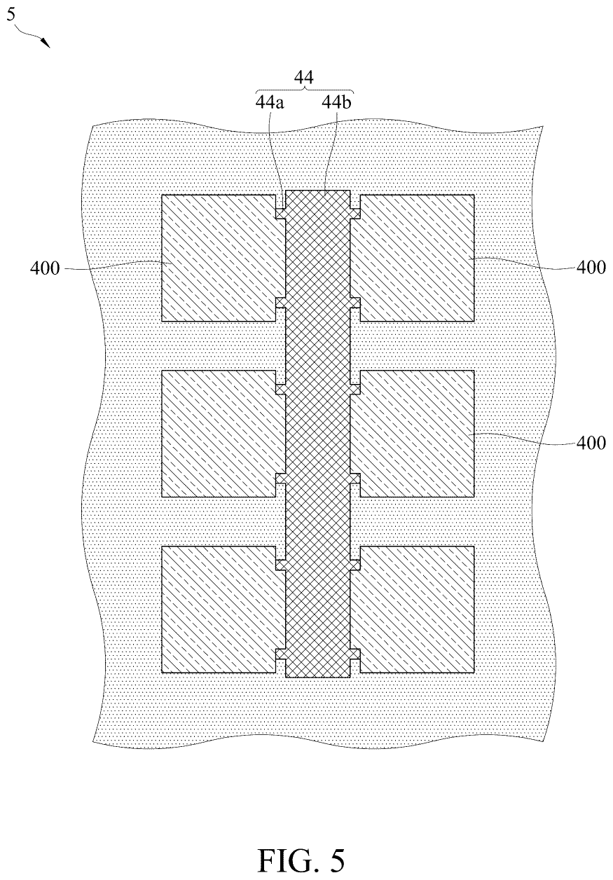

Please refer to FIG. 5, which is a schematic partial top planar view of a fourth embodiment of an electronic package 5 of the present disclosure. The embodiment is roughly the same as the previous embodiment, the main difference is that a plurality of bonding pads 400 (roughly in a convex shape [e.g., in a shape of “T” or in a shape of Chinese character “L”]) are formed on the carrier structure, and the plurality of bonding pads 400 are arranged in pairs in a row, the fillers 44 (roughly in a serially-connected convex shape [e.g., in a shape of Chinese character “#”]) located between the pairs of the bonding pads 400 at the same time are also connected to each other in a row.

Each filler 44 located between two bonding pads 400 is connected to the second section 44b of the adjacent filler 44 via the second section 44b thereof, wherein the second section 44b and the bonding pad 400 keep a distance therebetween.

To sum up, in the electronic package and carrier structure thereof of the present disclosure, a filler is formed between a pair of corresponding bonding pads to support the electronic element, the filler includes a first section connecting the bonding pads and a second section intersecting with the first section at the same time, and the second section is spaced apart from the bonding pads by a distance, thereby preventing the solder material from bridging at edges of the electronic element or the filler and from causing problems such as abnormalities or poor appearance when the electronic element is electrically connected to the bonding pads via the solder material.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A carrier structure, comprising:
a substrate body having a plurality of bonding pads; and
an insulating protective layer formed on the substrate body and having a plurality of openings correspondingly exposing the plurality of bonding pads and a slot communicating the plurality of openings, wherein the slot comprises a first slot connecting two adjacent ones of the plurality of openings and a second slot intersecting with the first slot, and the second slot is spaced apart from the bonding pads by a distance.

2. The carrier structure of claim 1, wherein the slot is in a cross shape and comprises the first slot and the second slot intersecting with the first slot.

3. The carrier structure of claim 1, wherein the slot is in a serially-connected convex shape and comprises two of the first slots and the second slot intersecting with the two of the first slots.

4. The carrier structure of claim 1, wherein a portion of the insulating protective layer is disposed between the second slot and the bonding pads.

5. The carrier structure of claim 1, wherein the plurality of bonding pads are arranged in pairs in a row, and the slots located between the pairs of the bonding pads are also connected to each other in a row.

6. The carrier structure of claim 1, wherein the bonding pads are in a convex shape, and outer convex portions of a pair of the bonding pads are opposite to each other.

7. An electronic package, comprising:
a carrier structure comprising a substrate body and an insulating protective layer formed on the substrate body, wherein the substrate body has a plurality of bonding pads, the insulating protective layer is formed with a plurality of openings for correspondingly exposing the plurality of bonding pads and a slot communicating the plurality of openings, wherein the slot comprises a first slot connecting two adjacent ones of the plurality of openings and a second slot intersecting with the first slot, and the second slot is spaced apart from the bonding pads by a distance;
a filler formed in the slot and comprising a first section corresponding to the first slot and a second section corresponding to the second slot, wherein the second section and the bonding pads are spaced by a distance therebetween; and
an electronic element disposed on the filler and electrically connected to two adjacent ones of the bonding pads via a solder material.

8. The electronic package of claim 7, wherein the filler is in contact with and bonded to the electronic element and the substrate body.

9. The electronic package of claim 7, wherein the electronic element is disposed on the first slot and two adjacent ones of the openings communicated by the first slot.

10. The electronic package of claim 7, wherein the filler is in a cross shape or in a serially-connected convex shape.

11. The electronic package of claim 7, wherein the first section of the filler corresponds to the first slot and a portion of the opening.

12. The electronic package of claim 7, wherein a portion of the insulating protective layer remains between a bottom of the filler and the bonding pads.

13. The electronic package of claim 7, wherein the plurality of bonding pads are arranged in pairs in a row, and the fillers located between the pairs of the bonding pads are also connected to each other in a row.

14. The electronic package of claim 7, wherein the slot is in a cross shape and comprises the first slot and the second slot intersecting with the first slot.

15. The electronic package of claim 7, wherein the slot is in a serially-connected convex shape and comprises the two first slots and the second slot intersecting with the two first slots.

16. The electronic package of claim 7, wherein a portion of the insulating protective layer is between the second slot and the bonding pads.

17. The electronic package of claim 7, wherein the plurality of bonding pads are arranged in pairs in a row, and the slots located between the pairs of the bonding pads are also connected to each other in a row.

18. The electronic package of claim 7, wherein the bonding pads are in a convex shape, and outer convex portions of a pair of the bonding pads are opposite to each other.
